(19) United States
(12) Patent Application Publication
(10) Pub. No.: US 2002/0096754 A1
(43) Pub. Date: Jul. 25, 2002

(54) Stacked structure of integrated circuits

(76) Inventors: Wen Chuan Chen, Hsinchu Hsien (TW); Kuo Feng Peng, Hsinchu Hsien (TW); C. H. Chou, Hsinchu Hsien (TW); Allis Chen, Hsinchu Hsien (TW); Nai Hua Yeh, Hsinch Hsien (TW); Yen Cheng Huang, Hsinchu Hsien (TW); C. F. Wang, Hsinchu Hsien (TW); Chen Pin Peng, Hsinchu Hsien (TW); Wen Tsan Lee, Hsinchu Hsien (TW); Jichen Wu, Hsinchu Hsien (TW)

Correspondence Address: Keith Kline, PRO-TECHTOR INTERNATIONAL SERVICES, 20775 Norada Court, Saratoga, CA, 95070-3018, US

(21) Appl. No.: 09/770,053

(22) Filed: Jan. 24, 2001

(51) Int. Cl. H01L 23/02; H01L 23/34; H01L 23/48; H01L 23/52; H01L 29/40

(52) U.S. Cl. 257/686; 257/685; 257/723; 257/738; 257/783

(57) ABSTRACT

A stacked structure of integrated circuits for electrically connecting to a circuit board includes a substrate, a lower integrated circuit, a plurality of wirings, and an upper integrated circuit. The lower integrated circuit has a lower surface and an upper surface. The lower surface is adhered onto the first surface of the substrate. A plurality of bonding pads are formed on the upper surface. The wirings each has a first end and a second end. The first ends of the wirings are electrically connected to the bonding pads of the lower integrated circuit. The second ends of the wirings are electrically connected to the signal input terminals of the substrate. The upper integrated circuit has a lower surface and an upper surface. Two recesses are formed at two sides of the lower surface. The upper integrated circuit is adhered to the upper surface of the lower integrated circuit so as to stack above the lower integrated circuit. Furthermore, the first ends of the plurality of wirings are located within the recesses. According to the structure, when stacking the upper integrated circuit above the lower integrated circuit, the wirings are free from being pressed and damaged. Moreover, two recesses may be formed at two sides of the lower surface of the lower integrated circuit so that overflowed glue can fill the recesses when adhering the lower integrated circuit onto the substrate. Thus, the size of the integrated circuit package can be reduced.

### BACKGROUND OF THE INVENTION

1. Field of the invention

The invention relates to a structure of stacked integrated circuits, in particular, to a structure of stacked integrated circuits in which integrated circuits can be effectively stacked so as to facilitate the manufacturing processes.

2. Description of the related art

In the current technological field, every product needs to be light, thin, and small. Therefore, it is preferable that the integrated circuit has a small volume in order to meet the demands of the products. In the prior art, even if the volumes of integrated circuits are small, they only can be electrically connected to the circuit board in parallel. Because the area of the circuit board is limited, it is not possible to increase the number of the integrated circuits mounted on the circuit board. Therefore, it is difficult to make the products small, thin, and light.

To meet the demands of manufacturing small, thin, and light products, a lot of integrated circuits can be stacked. However, when stacking a lot of integrated circuits, the upper integrated circuit will contact and press the wirings of the lower integrated circuit. In this case, the signal transmission to or from the lower integrated circuit is easily influenced.

Referring to FIG. 1, a structure of stacked integrated circuits includes a substrate 10, a lower integrated circuit 12, an upper integrated circuit 14, a plurality of wirings 16, and an isolation layer 18. The lower integrated circuit 12 is located on the substrate 10. The isolation layer 18 is located on the lower integrated circuit 12. The upper integrated circuit 14 is stacked on the isolation layer 18. That is, the upper integrated circuit 14 is stacked above the lower integrated circuit 12 with the isolation layer 18 interposed between the integrated circuits 12 and 14. Thus, a proper gap 20 is formed between the lower integrated circuit 12 and the upper integrated circuit 14. According to this structure, the plurality of wirings 16 can be electrically connected to the edge of the lower integrated circuit 12. Furthermore, the plurality of wirings 16 connecting the substrate 10 to the lower integrated circuit 12 are free from being pressed when stacking the upper integrated circuit 14 above the lower integrated circuit 12.

However, the above-mentioned structure has the disadvantages to be described hereinbelow. During the manufacturing processes, the isolation layer 18 has to be manufactured in advance, and then, it is adhered to the lower integrated circuit 12. Thereafter, the upper integrated circuit 14 has to be adhered on the isolation layer 18. As a result, the manufacturing processes are complicated, and the manufacturing costs are high.

To solve the above-mentioned problems, it is necessary for the invention to provide a structure of stacked integrated circuits in order to improve the stacking processes of the integrated circuits, facilitate the manufacturing processes, and lower down the manufacturing costs.

### SUMMARY OF THE INVENTION

It is therefore an object of the invention to provide a structure of stacked integrated circuits in order to effectively stack the integrated circuits and increase the manufacturing speed.

It is therefore another object of the invention to provide a stacked structure of integrated circuits in which overflowed glue can be avoided so as not to influence the electrical contact.

It is therefore still another object of the invention to provide a stacked structure of integrated circuits to reduce the area covered by the overflowed glue so that the size of the package can be reduced.

According to one aspect of the invention, a stacked structure of integrated circuits for electrically connecting to a circuit board includes a substrate, a lower integrated circuit, a plurality of wirings, and an upper integrated circuit. The lower integrated circuit has a lower surface and an upper surface. The lower surface is adhered onto the first surface of the substrate. A plurality of bonding pads are formed on the upper surface. Each of the wirings has a first end and a second end. The first ends of the wirings are electrically connected to the bonding pads of the lower integrated circuit. The second ends of the wirings are electrically connected to the signal input terminals of the substrate. The upper integrated circuit has a lower surface and an upper surface. Two recesses are formed at two sides of the lower surface. The upper integrated circuit is adhered to the upper surface of the lower integrated circuit so as to stack above the lower integrated circuit.

Furthermore, the first ends of the plurality of wirings are located within the recesses. According to the structure, when stacking the upper integrated circuit above the lower integrated circuit, the wirings are free from being pressed and damaged. Moreover, two recesses may be formed at two sides of the lower surface of the lower integrated circuit so that overflowed glue can fill the recesses when adhering the lower integrated circuit onto the substrate. Thus, the size of the integrated circuit package can be reduced.

### BRIEF DESCRIPTION OF THE DRAWINGS

FIG. 1 is a cross-sectional view showing a conventional stacked structure of integrated circuits.

FIG. 2 is a cross-sectional view showing a stacked structure of integrated circuits in accordance with a first embodiment of the invention.

FIG. 3 is a cross-sectional view showing a stacked structure of integrated circuits in accordance with a second embodiment of the invention.

FIG. 4 is a cross-sectional view showing a stacked structure of integrated circuits in accordance with a third embodiment of the invention.

FIG. 5 is a top view showing a wafer.

FIG. 6 is a schematic illustration showing the manufacturing processes for manufacturing the integrated circuit of the invention.

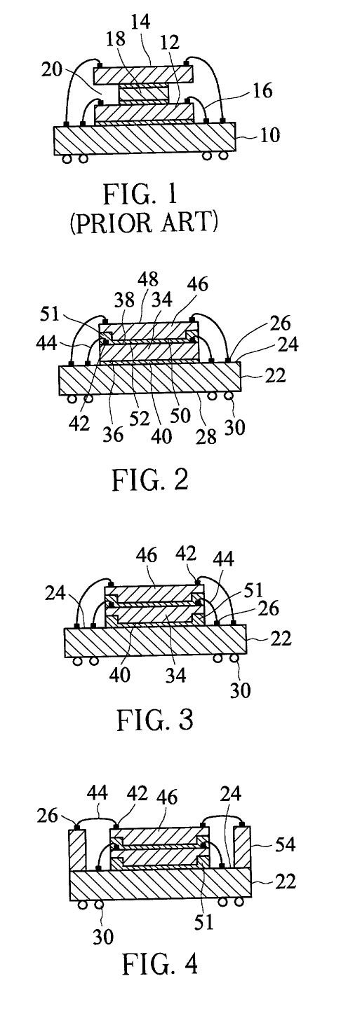

### DETAIL DESCRIPTION OF THE INVENTION

The embodiments of the invention will be described with reference to the accompanying drawings.

Referring to FIG. 2, the stacked structure of integrated circuits in accordance with an embodiment of the invention includes a substrate 22, a lower integrated circuit 34, a plurality of wirings 44, and an upper integrated circuit 46.

The substrate 22 has a first surface 24 and a second surface 28 opposite to the first surface 24. A plurality of signal input terminals 26 are formed on the first surface 24 for electrically connecting to an integrated circuit. A plurality of signal output terminals 30 are formed on the second surface 28 for electrically connecting to a circuit board (not shown). The signal output terminals 30 formed on the second surface 28 of the substrate 22 may be a plurality of metallic balls, arranged in the form of a ball grid array (BGA), for electrically connecting to the circuit board.

The lower integrated circuit 34 has a lower surface 36 and an upper surface 38 opposite to the lower surface 36. The lower surface 36 is adhered onto the first surface 24 of the substrate 22 through an adhesive layer 40. A plurality of bonding pads 42 are formed on the upper surface 38 for electrically connecting to the substrate 22. Thus, the signals from the lower integrated circuit 34 can be transmitted to the signal input terminals 26 formed on the first surface 24 of the substrate 22.

Each of the wirings 44 has a first end and a second end opposite to the first end. The first ends of the wirings 44 are electrically connected to the bonding pads 42 of the lower integrated circuit 34, respectively. The second ends of the wirings 44 are electrically connected to the signal input terminals 26 of the substrate 22. In this embodiment, the plurality of wirings 44 are electrically connected to the periphery of the lower integrated circuit 34 by way of wedge bonding. However, the plurality of wirings 44 also can be electrically connected to the bonding pads 42 of the lower integrated circuit 34 by way of ball bonding so that the signals from the lower integrated circuit 34 can be transmitted to the signal input terminals 26 formed on the first surface 24 of the substrate 22.

The upper integrated circuit 46 has an upper surface 48 and a lower surface 50 opposite to the upper surface 48. Two recesses 51 are formed at two sides of the lower surface 50. The upper integrated circuit 46 are adhered to the upper surface 38 of the lower integrated circuit 34 through an adhesive layer 52 so as to form a stack with the lower integrated circuit 34. The first ends of the wirings 44 are located within the recesses 51 so that the wirings 44 are free from be pressed and damaged by the upper integrated circuit 46.

Referring to FIG. 3, in addition to the above-mentioned structure as shown in FIG. 2, two recesses 51 may be also formed at two sides of the lower integrated circuit 34 in accordance with a second embodiment of the invention. At this case, the overflowed glue 54, caused by an improper control of the quantity of the adhesive layer 40, fills the recesses 51 of the lower integrated circuit 34 when adhering the lower integrated circuit 34 onto the first surface 24 of the substrate 22. Thus, the signal input terminals 26 of the substrate 22 are free from being covered by the overflowed glue 54, and the bonding processes are not adversely influenced. Consequently, the problems caused by the overflowed glue in the prior art never exist, and the substrate 22 needs not to be enlarged. Thus, the stacked structure of the embodiment can be a structure of a chip scale package.

Referring to FIG. 4, in addition to the above-mentioned structure as shown in FIG. 3, a projection 54 is further formed on the first surface 24 of the substrate 22 in accordance with a third embodiment of the invention. The signal input terminals 26 of the substrate 22 are formed on the projection 54 so that the wirings 44 of the upper integrated circuit 46 can be electrically connected to the projection 54. Thus, shorter wirings 44 can be used for connecting the upper integrated circuit 46 to the substrate 22, causing the signal transmission to be better.

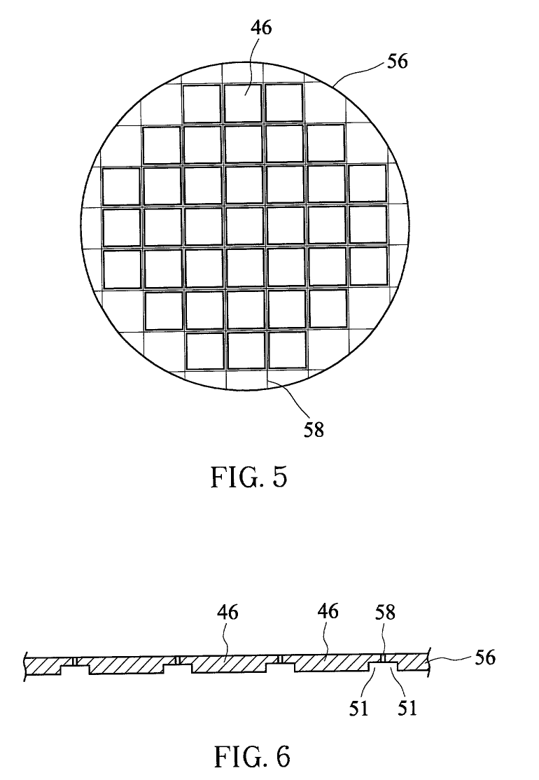

Referring to FIG. 5, a plurality of upper integrated circuits 46 are formed on a wafer 56. A plurality of scribing lines 58 are formed between each two adjacent upper integrated circuit 46, respectively. At this case, the processes for manufacturing the recesses 51 of the upper integrated circuit 46 can be described with reference to FIG. 6.

Referring to FIG. 6, first, recesses 51 are formed, without penetrating through the wafer 56, by scribing along the scribing lines 58 using a cutting tool with a larger width. Next, the wafer 56 is cut through along the scribing lines 58 using another cutting tool with a smaller width. Thus, each of the upper integrated circuits 46 on the wafer 56 can be separated, and recesses 51 can be formed in each of the upper integrated circuits 46.

According to the above-mentioned structure, the stacked structure of integrated circuits of the invention has the following advantages.

1. Since the first ends of the wirings 44 are located within the recesses 51 of the upper integrated circuit 46, the wirings 44 are free from being pressed and damaged by the upper integrated circuit 46 when stacking the upper integrated circuit 46 above the lower integrated circuit 34.

2. Since the problems caused by the overflowed glue can be avoided, a chip scale package, in which the substrate 22 can be the same size as the chip, can be performed.

While the invention has been described by way of example and in terms of preferred embodiments, it is to be understood that the invention is not limited to the disclosed embodiments. To the contrary, it is intended to cover various modifications. Therefore, the scope of the appended claims should be accorded the broadest interpretation so as to encompass all such modifications.

What is claimed is:

1. A stacked structure of integrated circuits for electrically connecting to a circuit board, comprising:
a substrate having a first surface and a second surface opposite to the first surface, the first surface being formed with a plurality of signal input terminals for electrically connecting to the integrated circuits, the second surface being formed with a plurality of signal output terminals for electrically connecting to the circuit board;
a lower integrated circuit having a lower surface and an upper surface opposite to the lower surface, the lower surface being adhered onto the first surface of the substrate, a plurality of bonding pads being formed on the upper surface;
a plurality of wirings each of which having a first end and a second end opposite to the first end, the first ends of the wirings being electrically connected to the bonding pads of the lower integrated circuit, the second ends of the wirings being electrically connected to the signal input terminals of the substrate; and
an upper integrated circuit having a lower surface and an upper surface opposite to the lower surface, two recesses being formed at two sides of the lower surface, wherein the upper integrated circuit is adhered to the upper surface of the lower integrated circuit so as to stack above the lower integrated circuit and the first ends of the plurality of wirings are located within the recesses.

2. The stacked structure of integrated circuits according to claim 1, wherein the signal output terminals of the substrate are metallic balls arranged in the form of a ball grid array (BGA).

3. The stacked structure of integrated circuits according to claim 1, wherein the plurality of wirings are electrically connected to the periphery of the second surface of the lower integrated circuit.

4. The stacked structure of integrated circuits according to claim 3, wherein the plurality of wirings are electrically connected to the lower integrated circuit by way of wedge bonding.

5. The stacked structure of integrated circuits according to claim 1, wherein two recesses are formed at two sides of the lower surface of the lower integrated circuit so that overflowed glue can fill the recesses when adhering the lower integrated circuit onto the substrate.

6. The stacked structure of integrated circuits according to claim 1, wherein the plurality of wirings are electrically connected to the bonding pads of the lower integrated circuit by way of ball bonding.

7. The stacked structure of integrated circuits according to claim 1, wherein a projection is formed on the first surface of the substrate, and the signal input terminals are formed on the projection so that the wirings electrically connect the upper integrated circuit to the signal input terminals on the projection.
